(19) United States
(12) Patent Application Publication
(10) Pub. No.: US 2012/0285508 A1
(43) Pub. Date: Nov. 15, 2012

(54) FOUR TERMINAL MULTI-JUNCTION THIN FILM PHOTOVOLTAIC DEVICE AND METHOD

(75) Inventor: Howard W.H. Lee, Saratoga, CA (US)

(73) Assignee: Stion Corporation, San Jose, CA (US)

(21) Appl. No.: 13/294,511

(22) Filed: Nov. 11, 2011

Related U.S. Application Data
(63) Continuation-in-part of application No. 12/512,979, filed on Jul. 30, 2009, now abandoned.
(60) Provisional application No. 61/092,732, filed on Aug. 28, 2008.

(51) Int. Cl. H01L 31/052

(52) U.S. Cl. 136/246

(57) ABSTRACT

A multi junction photovoltaic cell device includes a lower cell and an upper cell operably coupled to the lower cell. The lower cell includes a lower glass substrate material, a lower electrode, and a first terminal coupled to the lower electrode through the lower glass substrate material. The lower cell includes a lower absorber characterized by a bandgap smaller than 1 eV overlying the lower electrode and a lower window overlying the lower absorber and a lower transparent-conductive oxide coupled to a second terminal overlying the lower window. The upper cell includes a p+-type transparent conductor coupled to a third terminal. The upper cell further has an upper p-type absorber with a bandgap in a range of 1.6 to 1.9 eV overlying the p+-type transparent conductor and has an upper n-type window overlying the upper p-type absorber, an upper transparent-conductive oxide coupled to a fourth terminal overlying the upper n-type window.

### CROSS-REFERENCES TO RELATED APPLICATIONS

This application is a continuation-in-part of U.S. patent application Ser. No. 12/512,979, filed Jul. 30, 2009. This application claims priority of the U.S. patent application Ser. No. 12/512,979 which claims priority of U.S. Provisional Patent Application No. 61/092,732, filed Aug. 28, 2008, and further claims priority of U.S. patent application Ser. No. 13/189,508 which is a division of U.S. patent application Ser. No. 12/271,704 filed Nov. 14, 2008 further claiming priority to U.S. Provisional Patent Application No. 60/988,414, filed Nov. 15, 2007 and U.S. Provisional Patent Application No. 60/988,099, filed Nov. 14, 2007, commonly assigned and incorporated by reference herein for all purposes.

### BACKGROUND OF THE INVENTION

The present invention relates generally to photovoltaic materials and manufacturing method. More particularly, the present invention provides a method and structure for manufacture of high efficiency multi junction thin film photovoltaic cells. Merely by way of example, the present method and materials include absorber materials made of copper indium disulfide species, copper tin sulfide, iron disulfide, or others for multi junction cells.

From the beginning of time, mankind has been challenged to find way of harnessing energy. Energy comes in the forms such as petrochemical, hydroelectric, nuclear, wind, biomass, solar, and more primitive forms such as wood and coal. Over the past century, modern civilization has relied upon petrochemical energy as an important energy source. Petrochemical energy includes gas and oil. Gas includes lighter forms such as butane and propane, commonly used to heat homes and serve as fuel for cooking Gas also includes gasoline, diesel, and jet fuel, commonly used for transportation purposes. Heavier forms of petrochemicals can also be used to heat homes in some places. Unfortunately, the supply of petrochemical fuel is limited and essentially fixed based upon the amount available on the planet Earth. Additionally, as more people use petroleum products in growing amounts, it is rapidly becoming a scarce resource, which will eventually become depleted over time.

More recently, environmentally clean and renewable sources of energy have been desired. An example of a clean source of energy is hydroelectric power. Hydroelectric power is derived from electric generators driven by the flow of water produced by dams such as the Hoover Dam in Nevada. The electric power generated is used to power a large portion of the city of Los Angeles in California. Clean and renewable sources of energy also include wind, waves, biomass, and the like. That is, windmills convert wind energy into more useful forms of energy such as electricity. Still other types of clean energy include solar energy. Specific details of solar energy can be found throughout the present background and more particularly below.

Solar energy technology generally converts electromagnetic radiation from the sun to other useful forms of energy. These other forms of energy include thermal energy and electrical power. For electrical power applications, solar cells are often used. Although solar energy is environmentally clean and has been successful to a point, many limitations remain to be resolved before it becomes widely used throughout the world. As an example, one type of solar cell uses crystalline materials, which are derived from semiconductor material ingots. These crystalline materials can be used to fabricate optoelectronic devices that include photovoltaic and photodiode devices that convert electromagnetic radiation into electrical power. However, crystalline materials are often costly and difficult to make on a large scale. Additionally, devices made from such crystalline materials often have low energy conversion efficiencies. Other types of solar cells use “thin film” technology to form a thin film of photosensitive material to be used to convert electromagnetic radiation into electrical power. Similar limitations exist with the use of thin film technology in making solar cells. That is, efficiencies are often poor. Additionally, film reliability is often poor and cannot be used for extensive periods of time in conventional environmental applications. Often, thin films are difficult to mechanically integrate with each other. These and other limitations of these conventional technologies can be found throughout the present specification and more particularly below.

From the above, it is seen that improved techniques for manufacturing photovoltaic materials and resulting devices are desired.

### BRIEF SUMMARY OF THE INVENTION

According to embodiments of the present invention, a method and a structure for forming thin film semiconductor materials for photovoltaic applications are provided. More particularly, the present invention provides a method and structure for manufacture of high efficiency multi junction thin film photovoltaic cells. Merely by way of example, the present method and materials include absorber materials made of copper indium disulfide species, copper tin sulfide, iron disulfide, or others for multi junction cells.

In a specific embodiment, the present invention provides a multi junction photovoltaic cell device. The device includes a lower cell and an upper cell, which is operably coupled to the lower cell. In a specific embodiment, the lower cell includes a lower glass substrate material, e.g., transparent glass. The lower cell also includes a lower electrode layer made of a reflective material overlying the glass material. The lower cell includes a lower absorber layer overlying the lower electrode layer. In a specific embodiment, the absorber layer is made of a semiconductor material having a band gap energy in a range of, e.g., 0.7 to 1 eV, but can be others. In a specific embodiment, the lower cell includes a lower window layer overlying the lower absorber layer and a lower transparent conductive oxide layer overlying the lower window layer. The upper cell includes a p+ type transparent conductor layer overlying the lower transparent conductive oxide layer. In a preferred embodiment, the p+ type transparent conductor layer is characterized by traversing electromagnetic radiation in at least a wavelength range from about 700 to about 630 nanometers and filtering electromagnetic radiation in a wavelength range from about 490 to about 450 nanometers. In a specific embodiment, the upper cell has an upper p type absorber layer overlying the p+ type transparent conductor layer. In a preferred embodiment, the p type conductor layer made of a semiconductor material has a band gap energy in a range of, e.g., 1.6 to 1.9 eV, but can be others. The upper cell also has an upper n type window layer overlying the upper p type absorber layer, an upper transparent conductive oxide layer overlying the upper n type window layer, and an upper glass material overlying the upper transparent conductive oxide layer. Of course, there can be other variations, modifications, and alternatives.

Many benefits are achieved by ways of present invention. For example, the present invention uses starting materials that are commercially available to form a thin film of semiconductor bearing material overlying a suitable substrate member. The thin film of semiconductor bearing material can be further processed to form a semiconductor thin film material of desired characteristics, such as atomic stoichiometry, impurity concentration, carrier concentration, doping, and others. In a specific embodiment, the upper cell is configured to selectively filter certain wavelengths, while allowing others to pass and be processed in the lower cell. In a preferred embodiment, the upper cell configuration occurs using a preferred electrode layer, which can be combined or varied. In a preferred embodiment, the present configuration would replace the TCO, which is often an n+ type material, which is formed against a p type absorber leading to limitations, e.g., second junction. In a preferred embodiment, the present cell configuration and related method forms at least a p+ type buffer layer between the n+ type TCO from a lower cell and p type absorber from an upper cell. Again in a preferred embodiment, the present cell configuration and related method uses a p+ type transparent conductor that is not completely transparent across a range of wavelengths of sunlight but selectively allows passage of wavelengths in the red light range, which can be used in the lower cell. In a preferred embodiment, the p+ type transparent conductor material is characterized by about the same bandgap as the absorber layer and improves efficiency of the upper cell. Additionally, the present method uses environmentally friendly materials that are relatively less toxic than other thin-film photovoltaic materials. Depending on the embodiment, one or more of the benefits can be achieved. These and other benefits will be described in more detailed throughout the present specification and particularly below.

Merely by way of example, the present method and materials include absorber materials made of copper indium disulfide species, copper tin sulfide, iron disulfide, or others for single junction cells or multi junction cells. Other materials can also be used according to a specific embodiment.

### BRIEF DESCRIPTION OF THE DRAWINGS

FIG. 1 is a simplified diagram of four terminal multi junction photovoltaic cell according to an embodiment of the present invention.

FIG. 2 is a simplified diagram of a cross-sectional view diagram of a multi-junction photovoltaic cell according to an embodiment of the present invention.

FIG. 3 is a simplified diagram illustrating a selective filtering process according to a specific embodiment of the present invention.

FIG. 4 is a simplified diagram illustrating a photovoltaic cell structure according to an embodiment of the present invention.

FIG. 5 is a simplified circuit diagram illustrating the photovoltaic cell structure in FIG. 4.

FIG. 6 is a simplified diagram illustrating an alternative photovoltaic cell structure according to an embodiment of the present invention.

FIG. 7 is a simplified circuit diagram illustrating the photovoltaic cell structure in FIG. 5.

FIG. 8 is a simplified diagram illustrating an alternative photovoltaic cell structure according to an embodiment of the present invention.

FIG. 9 is a simplified circuit diagram illustrating the photovoltaic cell structure in FIG. 8.

FIG. 10 is a simplified diagram illustrating an example of a photovoltaic cell structure according to an embodiment of the present invention.

### DETAILED DESCRIPTION OF THE INVENTION

According to embodiments of the present invention, a method and a structure for forming thin film semiconductor materials for photovoltaic applications are provided. More particularly, the present invention provides a method and structure for manufacture of high efficiency multi junction thin film photovoltaic cells. Merely by way of example, the present method and materials include absorber materials made of copper indium disulfide species, copper tin sulfide, iron disulfide, or others for multi junction cells.

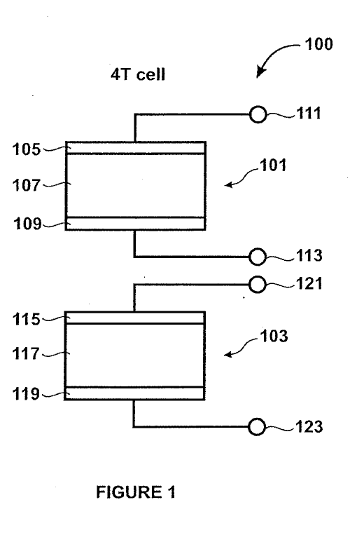

FIG. 1 is a simplified diagram 100 of a four terminal multi junction photovoltaic cell according to an embodiment of the present invention. The diagram is merely an illustration and should not unduly limit the scope of the claims herein. One of ordinary skill in the art would recognize other variations, modifications, and alternatives. As shown, the present invention provides a multi junction photovoltaic cell device 100. The device includes a lower cell 103 and an upper cell 101, which is operably coupled to the lower cell. In a specific embodiment, the term lower and upper are not intended to be limiting but should be construed by plain meaning by one of ordinary skill in the art. In general, the upper cell is closer to a source of electromagnetic radiation, than the lower cell, which receives the electromagnetic radiation after traversing through the upper cell. Of course, there can be other variations, modifications, and alternatives.

In a specific embodiment, the lower cell includes a lower glass substrate material 119, e.g., transparent glass, soda lime glass, or other optically transparent substrate or other substrate, which may not be transparent. The lower cell also includes a lower electrode layer made of a reflective material overlying the glass material. The lower cell includes a lower absorber layer overlying the lower electrode layer. As shown, the absorber and electrode layer are illustrated by reference numeral 117. In a specific embodiment, the absorber layer is made of a semiconductor material having a band gap energy in a range of, e.g., 0.7 to 1 eV, but can be others. In a specific embodiment, the lower cell includes a lower window layer overlying the lower absorber layer and a lower transparent conductive oxide layer 115 overlying the lower window layer.

In a specific embodiment, the upper cell includes a p+ type transparent conductor layer 109 overlying the lower transparent conductive oxide layer. In a preferred embodiment, the p+ type transparent conductor layer is characterized by traversing electromagnetic radiation in at least a wavelength range from about 700 to about 630 nanometers and filtering electromagnetic radiation in a wavelength range from about 490 to about 450 nanometers. In a specific embodiment, the upper cell has an upper p type absorber layer overlying the p+ type transparent conductor layer. In a preferred embodiment, the p type conductor layer made of a semiconductor material has a band gap energy in a range of, e.g., 1.6 to 1.9 eV, but can be others. The upper cell also has an upper n type window layer overlying the upper p type absorber layer. Referring again to FIG. 1, the window and absorber are illustrated by reference numeral 107. The upper cell also has an upper transparent conductive oxide layer 105 overlying the upper n type window layer and an upper glass material overlying the upper transparent conductive oxide layer. Of course, there can be other variations, modifications, and alternatives.

In a specific embodiment, the multi junction photovoltaic cell includes four terminals. The four terminals are defined by reference numerals 111, 113, 121, and 123. Alternatively, the multi junction photovoltaic cell can also include three terminals, which share a common electrode preferably proximate to an interface region between the upper cell and the lower cell. In other embodiments, the multi junction cell can also include two terminals, among others, depending upon the application. Examples of other cell configurations are provided in U.S. Provisional Patent Application No. 60/988,414, filed Nov. 11, 2007, commonly assigned and incorporated by reference herein in its entirety for all purposes. Of course, there can be other variations, modifications, and alternatives. Further details of the four terminal cell can be found throughout the present specification and more particularly below.

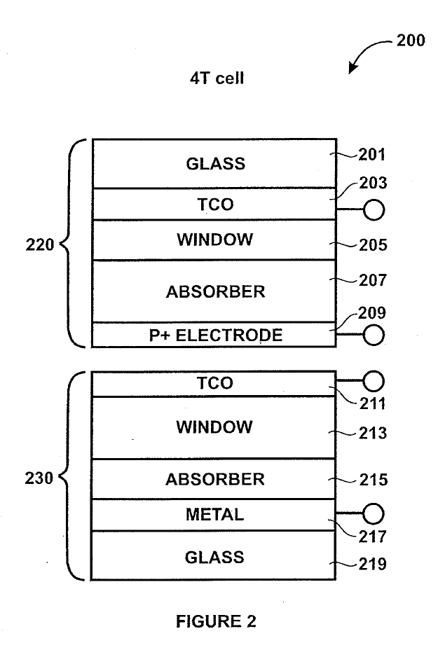

FIG. 2 is a simplified cross-sectional view diagram of a multi junction photovoltaic cell 200 according to an embodiment of the present invention. The diagram is merely an illustration and should not be construed to unduly limit the scope of the claims herein. One of ordinary skill in the art would recognize other variations, modifications, and alternatives. As shown, the present invention provides a multi junction photovoltaic cell device 200. The device includes a lower cell 230 and an upper cell 220, which is operably coupled to the lower cell. In a specific embodiment, the term lower and upper are not intended to be limiting but should be construed by plain meaning by one of ordinary skill in the art. In general, the upper cell is closer to a source of electromagnetic radiation, than the lower cell, which receives the electromagnetic radiation after traversing through the upper cell. Of course, there can be other variations, modifications, and alternatives.

In a specific embodiment, the lower cell includes a lower glass substrate material 219, e.g., transparent glass, soda lime glass, or other optically transparent substrate or other substrate, which may not be transparent. The glass material or substrate can also be replaced by other materials such as a polymer material, a metal material, or a semiconductor material, or any combinations of them. Additionally, the substrate can be rigid, flexible, or any shape and/or form depending upon the embodiment. Of course, there can be other variations, modifications, and alternatives.

In a specific embodiment, the lower cell also includes a lower electrode layer 217 made of a reflective material overlying the glass material. The reflective material can be a single homogeneous material, composite, or layered structure according to a specific embodiment. In a specific embodiment, the lower electrode layer is made of a material selected from aluminum, silver, gold, molybdenum, copper, other metals, and/or conductive dielectric film(s), and others. The lower reflective layer reflects electromagnetic radiation that traversed through the one or more cells back to the one or more cells for producing current via the one or more cells. Of course, there can be other variations, modifications, and alternatives.

As shown, the lower cell includes a lower absorber layer 215 overlying the lower electrode layer. In a specific embodiment, the absorber layer is made of a semiconductor material having a band gap energy in a range of, e.g., 0.7 to 1 eV, but can be others. In a specific embodiment, the lower absorber layer is made of the semiconductor material selected from Cu₂SnS₃, FeS₂, and CuInSe₂. The lower absorber layer comprises a thickness ranging from about a first determined amount to a second determined amount, but can be others. Depending upon the embodiment, the lower cell can be formed using a copper indium gallium selenide (CIGS), which is copper, indium, gallium, and selenium. Of course, there can be other variations, modifications, and alternatives.

In a specific embodiment, the material includes copper indium selenide (“CIS”) and copper gallium selenide, with a chemical formula of CuInₓGa₍₁₋ₓ₎Se₂, where the value of x can vary from 1 (pure copper indium selenide) to 0 (pure copper gallium selenide). In a specific embodiment, the CIGS material is characterized by a bandgap varying with x from about 1.0 eV to about 1.7 eV, but may be others, although the band gap energy is preferably between about 0.7 to about 1.1 eV. In a specific embodiment, the CIGS structures can include those described in U.S. Pat. Nos. 4,611,091 and 4,612,411, which are hereby incorporated by reference herein, as well as other structures. Of course, there can be other variations, modifications, and alternatives.

In a specific embodiment, the lower cell includes a lower window layer overlying the lower absorber layer and a lower transparent conductive oxide layer 215 overlying the lower window layer. In a specific embodiment, the lower window layer is made of material selected from cadmium sulfide, cadmium zinc sulfide, or other suitable materials. In other embodiments, other n-type compound semiconductor layer include, but are not limited to, n-type group II-VI compound semiconductors such as zinc selenide, cadmium selenide, but can be others. Of course, there can be other variations, modifications, and alternatives. The transparent conductor oxide layer is indium tin oxide or other suitable materials.

In a specific embodiment, the upper cell includes a p+ type transparent conductor layer 209 overlying the lower transparent conductive oxide layer. In a preferred embodiment, the p+ type transparent conductor layer is characterized by traversing electromagnetic radiation in at least a wavelength range from about 700 nanometers to about 630 nanometers and filtering electromagnetic radiation in a wavelength range from about 490 nanometers to about 450 nanometers. In a preferred embodiment, the p+ type transparent conductor layer comprises a ZnTe species, including ZnTe crystalline material or polycrystalline material. In one or more embodiments, the p+ type transparent conductor layer is doped with at least one or more species selected from Cu, Cr, Mg, O, Al, or N, combinations, among others. In a preferred embodiment, the p+ type transparent conductor layer is characterized to selectively allow passage of red light and filter out blue light having a wavelength ranging from about 400 nanometers to about 450 nanometers. Also in a preferred embodiment, the p+ type transparent conductor layer is characterized by a band gap energy in a range of, e.g., 1.6 to 1.9 eV, or a band gap similar to the upper p type absorber layer. Of course, there can be other variations, modifications, and alternatives.

In a specific embodiment, the upper cell has an upper p type absorber layer 207 overlying the p+ type transparent conductor layer. In a preferred embodiment, the p type conductor layer made of a semiconductor material has a band gap energy in a range of, e.g., 1.6 to 1.9 eV, but can be others. In a specific embodiment, the upper p type absorber layer is selected from CuInS₂, Cu(In,Al)S₂, Cu(In,Ga)S₂, or other suitable materials. The absorber layer is made using suitable techniques, such as those described in U.S. Provisional Patent Application No. 61/059,253 filed Jun. 5, 2008, commonly assigned, and hereby incorporated by reference here.

Referring back to FIG. 2, the upper cell also has an upper n type window layer 205 overlying the upper p type absorber layer. In a specific embodiment, the n type window layer is selected from a cadmium sulfide (CdS), a zinc sulfide (ZnS), zinc selenium (ZnSe), zinc oxide (ZnO), zinc magnesium oxide (ZnMgO), or others and may be doped with impurities for conductivity, e.g., n⁺ type. The upper cell also has an upper transparent conductive oxide layer 203 overlying the upper n type window layer according to a specific embodiment. The transparent oxide can be indium tin oxide and other suitable materials. For example, TCO can be selected from a group consisting of In₂O₃:Sn (ITO), ZnO:Al (AZO), SnO₂:F (TFO), and can be others.

In a specific embodiment, the upper cell also includes a cover glass 201 or upper glass material overlying the upper transparent conductive oxide layer. The upper glass material provides suitable support for mechanical impact and rigidity. The upper glass can be transparent glass or others. Of course, there can be other variations, modifications, and alternatives.

In a specific embodiment, the multi junction photovoltaic cell includes upper cell 220, which is coupled to lower cell 230, in a four terminal configuration. Alternatively as noted, the multi junction photovoltaic cell can also include three terminals, which share a common electrode preferably proximate to an interface region between the upper cell and the lower cell. In other embodiments, the multi junction cell can also include two terminals, among others, depending upon the application. Of course, there can be other variations, modifications, and alternatives. Further details of the four terminal cell can be found throughout the present specification and more particularly below.

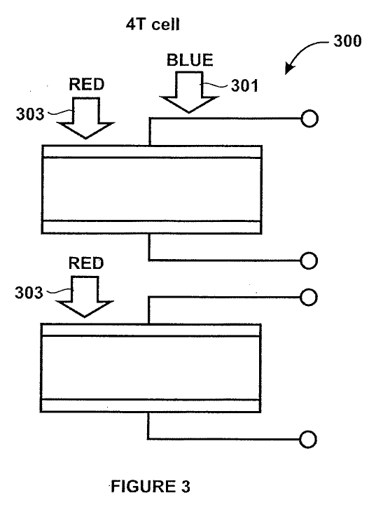

FIG. 3 is a simplified diagram illustrating a selective filtering process according to a specific embodiment of the present invention. The diagram is merely an illustration and should not unduly limit the scope of the claims herein. One of ordinary skill in the art would recognize other variations, modifications, and alternatives. As shown is a method for using a multi junction photovoltaic cell, such as those described in the present specification. In a specific embodiment, the method includes irradiating sunlight through an upper cell operably coupled to a lower cell. As shown, the irradiation generally includes wavelengths corresponding to blue light 301 and red light 303, including slight or other variations. In a specific embodiment, the upper cell comprising a p+ type transparent conductor layer overlying a lower transparent conductive oxide layer. The p+ type conductor layer is also coupled to a p-type absorber layer and also has a substantially similar band gap as the absorber layer to effectively lengthen the absorber layer. As shown, the method selectively allows for traversing the electromagnetic radiation from the sunlight in at least a wavelength range from about 700 nanometers to about 630 nanometers through the p+ type transparent conductor layer. In a preferred embodiment, the p+ type conductor layer also filters out or blocks electromagnetic radiation in a wavelength range from about 490 to about 450 nanometers through the p+ type transparent conductor layer. Depending upon the embodiment, the method also includes other variations. In a specific embodiment, the colors of the visible light spectrum color wavelength interval frequency interval are listed below.
red˜700 nm-630 nm˜430-480 THz
orange˜630 nm-590 nm˜480-510 THz
yellow˜590 nm-560 nm˜510-540 THz
green˜560 nm-490 nm˜540-610 THz
blue˜490 nm-450 nm˜610-670 THz
violet˜450 nm-400 nm˜670-750 THz

In a preferred embodiment, the present multi junction cell has improved efficiencies. As an example, the present multi junction cell has an upper cell made of CuInS₂ that has an efficiency of about 12.5% and greater or 10% and greater according to a specific embodiment. The efficiency is commonly called a “power efficiency” measured by electrical power out/optical power in. Of course, there may also be other variations, modifications, and alternatives.

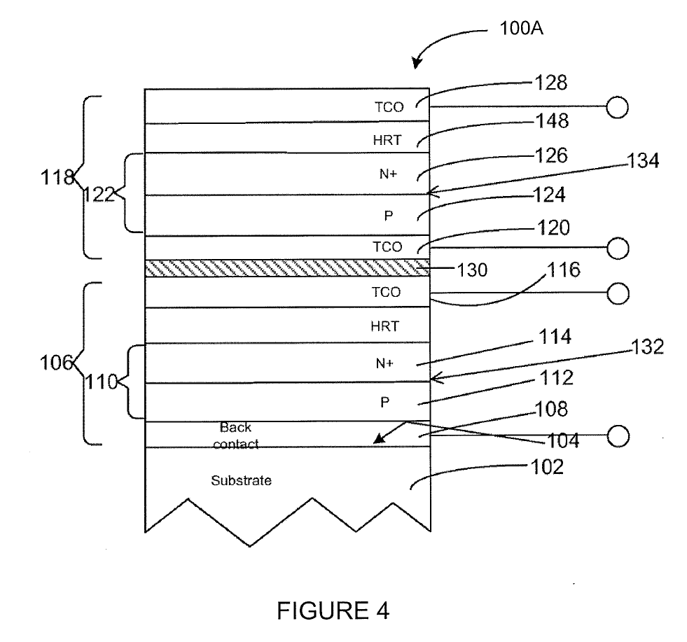

FIG. 4 is a simplified diagram illustrating a photovoltaic cell structure for manufacturing a multi junction solar module according to an alternative embodiment of the present invention. In a specific embodiment, the photovoltaic cell structure 100A is an example of the four-terminal multi junction cell device 100 shown in FIG. 1 and device 200 shown in FIG. 2. As shown, the photovoltaic cell structure 100A includes a substrate member 102 having a surface region 104. The substrate member can be made of an insulator material, a conductor material, or a semiconductor material, depending on the application. In a specific embodiment, the conductor material can be nickel, molybdenum, aluminum, or a metal alloy such as stainless steel and the likes. In a specific embodiment, the semiconductor material may include silicon, germanium, silicon germanium, compound semiconductor material such as III-V materials, II-VI materials, and others. In a specific embodiment, the insulator material can be a transparent material such as glass, quartz, fused silica, and the like. Alternatively, the insulator material can be a polymer material, a ceramic material, or a layer material or a composite material depending on the application. The polymer material may include acrylic material, polycarbonate material, and others, depending on the embodiment. Of course, there can be other variations modifications, and alternatives.

As shown in FIG. 4, the photovoltaic cell structure 100A includes a first photovoltaic cell structure 106. In a specific embodiment, the first photovoltaic cell structure 106 is an example of the lower cell 103 with two terminals as shown in FIG. 1. The first photovoltaic cell structure 106 includes a first electrode structure 108. In a specific embodiment, the first electrode structure 108 uses a first conductor material characterized by a resistivity less than about 10 Ohm-cm. The first electrode structure 108 can be made of a suitable material or a combination of materials. The first electrode structure 108 can be made from a transparent conductive electrode or materials that are light reflecting or light blocking depending on the embodiment. Examples of the transparent conductive electrode can include indium tin oxide (ITO), aluminum doped zinc oxide, fluorine doped tin oxide and others. In a specific embodiment, the transparent conductive electrode may be provided using techniques such as sputtering, chemical vapor deposition, electrochemical deposition, and others. In a specific embodiment, the first electrode structure may be made from a metal material. The metal material can include gold, silver, nickel, platinum, aluminum, tungsten, molybdenum, a combination of these, or an alloy, among others. In a specific embodiment, the metal material may be deposited using techniques such as sputtering, electroplating, electrochemical deposition and others. Alternatively, the first electrode structure may be made of a carbon based material such as carbon or graphite. Yet alternatively, the first electrode structure may be made of a conductive polymer material, depending on the application. Of course there can be other variations, modifications, and alternatives, modifications, and alternatives.

Referring again to FIG. 4, the first photovoltaic cell structure includes a lower cell junction 110 overlying the first electrode structure. In a specific embodiment, the lower cell junction 110 includes a first absorber layer 112 characterized by a P type impurity characteristics. That is, the first absorber layer 112 absorbs electromagnetic radiation forming positively charged carriers within the first absorber layer. In a specific embodiment, the first absorber layer 112 comprises a first metal chalcogenide semiconductor material and/or other suitable semiconductor material. The first absorber layer is characterized by a bandgap. In a specific embodiment, the first absorber layer has a first bandgap of ranging from about 0.7 eV to about 1.2 eV. In an alternative embodiment, the first absorber layer can have a first bandgap of about 0.5 eV to about 1.2 eV. In a preferred embodiment, the first absorber layer can have a bandgap of about 0.5 eV to about 1.0 eV. The first metal chalcogenide semiconductor material can include a suitable metal oxide. Alternatively, the first metal chalcogenide semiconductor material can include a suitable metal sulfide. Yet alternatively first metal chalcogenide semiconductor material can include a metal telluride or metal selenide depending on the application. In certain embodiments, the first absorber layer can be provided using a metal silicide material such as iron disilicide material, which has a P type impurity characteristics, and others. In a specific embodiment, the first absorber layer can be deposited using techniques such as sputtering, spin coating, doctor blading, powder coating, electrochemical deposition, inkjeting, among others, depending on the application. Of course there can be other variations, modifications, and alternatives.

In a specific embodiment, the first absorber layer has an optical absorption coefficient greater than about 10⁴ cm⁻¹ for electromagnetic radiation in a wavelength range of about 400 nm to about 800 nm. In an alternative embodiment, the first absorber layer can have an optical absorption coefficient greater than about 10⁴ cm⁻¹ for electromagnetic radiation in a wavelength range of about 450 nm to about 700 nm. Of course there can be other variations, modifications, and alternatives.

Referring to FIG. 4, the lower cell includes a first window layer 114 overlying the first absorber layer 112. In a specific embodiment, the first window layer has an N⁺ impurity type characteristics. In a preferred embodiment, the first window layer is characterized by a bandgap greater than about 2.5 eV, for example ranging from 2.5 eV to about 5.5 eV. In a specific embodiment, the first window layer comprises a second metal chalcogenide semiconductor material and/or other suitable semiconductor material. Alternatively, the second metal chalcogenide semiconductor material can comprise a semiconductor metal sulfide, a semiconductor metal oxide, a semiconductor metal telluride or a semiconductor metal selenide material. In certain embodiment, the first window layer may use an n-type zinc sulfide material for an iron disilicide material as the first absorber layer. In a specific embodiment, the first window layer can be deposited using techniques such as sputtering, spin coating, doctor blading, powder coating, electrochemical deposition, inkjeting, among others, depending on the application. Of course there can be other variations, modifications, and alternatives.

Again referring to FIG. 4, the first photovoltaic cell structure 106 includes a second electrode structure 116 overlying the lower cell in a specific embodiment. The second electrode structure is in electrical contact with the window layer in a specific embodiment. In a specific embodiment, the second electrode structure uses a conductor material characterized by a resistivity less than about 10 Ohm-cm. In a specific embodiment, the second electrode structure can be made of a suitable material or a combination of materials. The second electrode structure is preferably made from a transparent conductive electrode material. Materials that are light reflecting or light blocking may also be used depending on the embodiment. Examples of the optically transparent material can include indium tin oxide (ITO), aluminum doped zinc oxide, fluorine doped tin oxide and others. In an alternative embodiment, the second electrode structure may be made from a metal material. The metal material can include gold, silver, nickel, platinum, aluminum, tungsten, molybdenum, a combination of these, or an alloy, among others. In a specific embodiment, the metal material may be deposited using techniques such as sputtering, electroplating, electrochemical deposition and others. Yet alternatively, the second electrode structure may be made of a carbon based material such as carbon or graphite. In certain embodiments, the second electrode structure may be made of a conductive polymer material, depending on the application. Of course there can be other variations, modifications, and alternatives.

As shown in FIG. 4, photovoltaic cell structure 100A includes a second photovoltaic cell structure 118. In a specific embodiment, the second photovoltaic cell structure 118 is an example of the upper cell 101 with two terminals as shown in FIG. 1. The second photovoltaic cell structure 118 includes a third electrode structure 120. In a specific embodiment, the third electrode structure uses a conductor material characterized by a resistivity less than about 10 Ohm-cm. In a specific embodiment, the third electrode structure can be made of a suitable material or a combination of materials. The third electrode structure is preferably made from a transparent conductive electrode. Materials that are light reflecting or light blocking may also be used depending on the embodiment. Examples of the optically transparent material can include indium tin oxide (ITO), aluminum doped zinc oxide, fluorine doped tin oxide and others. In an alternative embodiment, the second electrode structure may be made from a metal material. The metal material can include gold, silver, nickel, platinum, aluminum, tungsten, molybdenum, a combination of these, or an alloy, among others. In a specific embodiment, the metal material may be deposited using techniques such as sputtering, electroplating, electrochemical deposition, and others. Yet alternatively, the second electrode structure may be made of a carbon based material such as carbon or graphite. In certain embodiments, the second electrode structure may be made of a conductive polymer material, depending on the application. Of course there can be other variations, modifications, and alternatives.

The upper photovoltaic cell includes an upper cell junction 122 overlying the third electrode structure 120. The upper cell junction includes a second absorber layer 124 overlying the third electrode structure 120. In a specific embodiment, the second absorber layer is characterized by a P type impurity characteristics. That is, the second absorber layer absorbs electromagnetic radiation forming positively charged carriers within the second absorber layer. In a specific embodiment, the second absorber layer comprises a third metal chalcogenide semiconductor material. The third metal chalcogenide semiconductor material is characterized by a second bandgap. In a specific embodiment, the second bandgap is greater than the first bandgap. In a specific embodiment, the second bandgap can range from about 1.0 eV to about 2.2 eV. In an alternative embodiment, the second bandgap can range from about 1.0 eV to about 2.5 eV. In a preferred embodiment, the third bandgap can range from about 1.2 eV to about 1.8 eV. The third metal chalcogenide semiconductor material can include a suitable semiconductor metal oxide. Alternatively, the third metal chalcogenide semiconductor material can include a suitable metal sulfide. Yet alternatively third metal chalcogenide semiconductor material can include a suitable semiconductor metal telluride or metal selenide depending on the application. In a specific embodiment, the second absorber layer is provided using a copper oxide material, which has a p type impurity characteristics. Of course there can be other variations, modifications, and alternatives.

Referring again to FIG. 4, the upper cell includes a second window layer 126. In a specific embodiment, the second window layer has an N⁻ impurity type characteristics. In a specific embodiment, the second window layer is characterized by a bandgap greater than about 2.5 eV, for example, ranging from about 2.5 eV to 5.0 eV. In a specific embodiment, the second window layer comprises a fourth metal chalcogenide semiconductor material. The fourth metal chalcogenide semiconductor material can include a suitable semiconductor metal sulfide, a suitable semiconductor metal oxide, a suitable semiconductor metal telluride or a suitable semiconductor metal selenide material. In a specific embodiment, the second window layer may be provided using a zinc sulfide material, which has an N type impurity characteristics. In a specific embodiment, the second window layer may be deposited using techniques such as sputtering, doctor blading, inkjeting, electrochemical deposition, and others.

In a specific embodiment, the second photovoltaic cell structure 118 includes a fourth electrode structure 128 overlying the upper cell junction. In a specific embodiment, the fourth electrode structure uses a conductor material characterized by a resistivity less than about 10 Ohm-cm. In a specific embodiment, the fourth electrode structure can be made of a suitable material or a combination of materials. The fourth electrode structure is preferably a transparent conductive electrode. Materials that are light reflecting or light blocking may also be used depending on the embodiment. Examples of the transparent conductive electrode can include indium tin oxide (ITO), aluminum doped zinc oxide, fluorine doped tin oxide and others. In an alternative embodiment, the fourth electrode structure may be made from a metal material. The metal material can include gold, silver, nickel, platinum, aluminum, tungsten, molybdenum, a combination of these, or an alloy, among others. In a specific embodiment, the metal material may be deposited using techniques such as sputtering, electroplating, electrochemical deposition and others. Yet alternatively, the fourth electrode structure may be made of a carbon based material such as carbon or graphite. In certain embodiments, the fourth electrode structure may be made of a conductive polymer material, depending on the application. Of course there can be other variations, modifications, and alternatives.

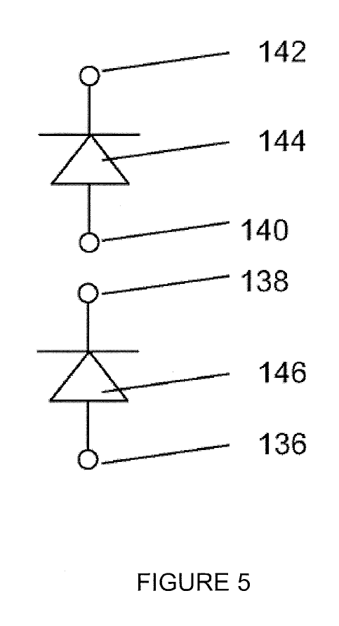

In a specific embodiment, the first photovoltaic cell structure 106 and the second photovoltaic cell structure 118 are coupled together using a glue layer 130 to form a multi-junction photovoltaic cell structure 100A as shown in FIG. 4. The glue layer is also applied to operably couple the second terminal 121 to the third terminal 113 of the four terminal cell 100 as shown in FIG. 1. As shown, the photovoltaic cell structure 100A includes a first junction region 132 caused by the first absorber layer and the first window layer. Photovoltaic cell structure 100A includes also a second junction region 134 caused by the second absorber layer and the second window layer. The glue layer is a suitable material that has desirable optical and mechanical characteristics. Such material can be ethyl vinyl acetate or polyvinyl butyral and the like, but can also be others. As shown in FIG. 5 a simplified circuit representation of the multi junction cell structure is depicted. As shown, the multi-junction photovoltaic cell structure has four terminals 136, 138, 140, and 142 provided by the first electrode structure, the second electrode structure, the third electrode structure, and the fourth electrode structure. The multi junction photovoltaic cell has two photodiodes 144 and 146 as provided by the upper cell and the lower cells. Of course one skilled in the art would recognize other variations, modifications, and alternative.

In a specific embodiment, the photovoltaic cell structure can have a buffer layer 148 disposed between the second conductor structure and the second window layer of the upper cell as shown in FIG. 4. The buffer layer is characterized by a resistivity greater than about 10 kOhm-cm and is preferably optically transparent in a specific embodiment. Of course there can be other variations, modifications, and alternatives.

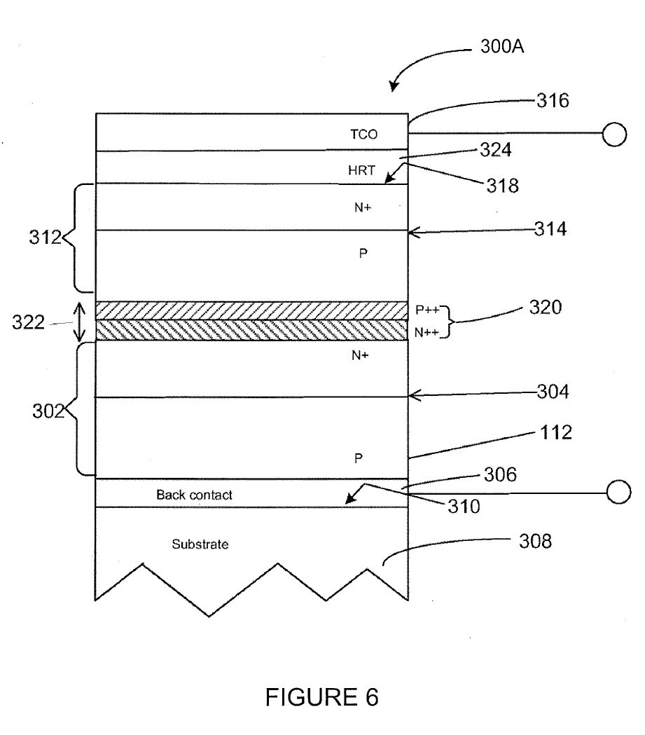

FIG. 6 is a simplified diagram illustrating another photovoltaic cell structure 300A for the manufacture of a multi junction solar cell module according to an alternative embodiment of the present invention. Photovoltaic cell structure 300A is configured to have two junctions and two electrodes. As shown, photovoltaic cell structure 300A includes a lower cell 302 which includes a first pn⁺-junction 304. The lower cell can have a same material composition as the lower cell as described above in connection with the photovoltaic cell structure in FIG. 4. The lower cell is in electrical contact with a first electrode structure 306 which overlies a surface region 310 of a substrate member 308 also as described above for FIG. 4.

Photovoltaic cell 300A further includes an upper cell 312 which includes a second pn⁻-junction 314. The upper cell also has a same material composition as the upper cell as described above in connection with the photovoltaic cell structure in FIG. 4. A second electrode structure 316 overlies and in electrical contact with a surface region 318 of the upper cell.

In a specific embodiment, a tunneling junction layer 320 is provided between the upper cell 312 and the lower cell 302 as shown in FIG. 6. The tunneling junction layer comprises a p⁻⁺/n⁺⁺ layer and is characterized by a thickness 322. In a specific embodiment, the tunneling junction layer can be adjusted, either by way of thickness, or by way of dopant characteristics, to provide an optimized current flow between the upper cell and the lower cell. Of course there can be other variations, modifications, and alternatives.

Optionally, photovoltaic cell structure 300A can include a buffer layer 324 disposed between the second conductor structure and the upper cell. The buffer layer prevents diffusion of, for example, electrode materials into the photovoltaic cell in subsequent high temperature processing steps. Buffer layer 324 may be made from a high resistance transparent material having a resistivity greater than 10 kOhm-cm in a specific embodiment. Example of such high resistance transparent material can include intrinsic semiconductor such as intrinsic zinc oxide, intrinsic zinc sulfide and the like. Of course there can be other variations, modifications, and alternatives.

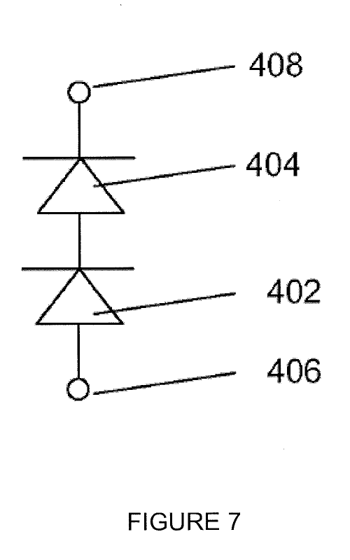

FIG. 7 is a simplified circuit diagram for photovoltaic cell structure 300A according to an embodiment of the present invention. As shown, the photovoltaic cell structure includes a first photodiode 402, a second photodiode 404, a first electrode terminal 406, and a second electrode terminal 408. Photovoltaic cell structure 300A can be characterized by two junctions, provided by each of the photodiodes and two electrode terminals. The first photodiode and the second photodiode are connected in series by means of the tunneling junction. Of course there can be other variations, modifications, and alternatives.

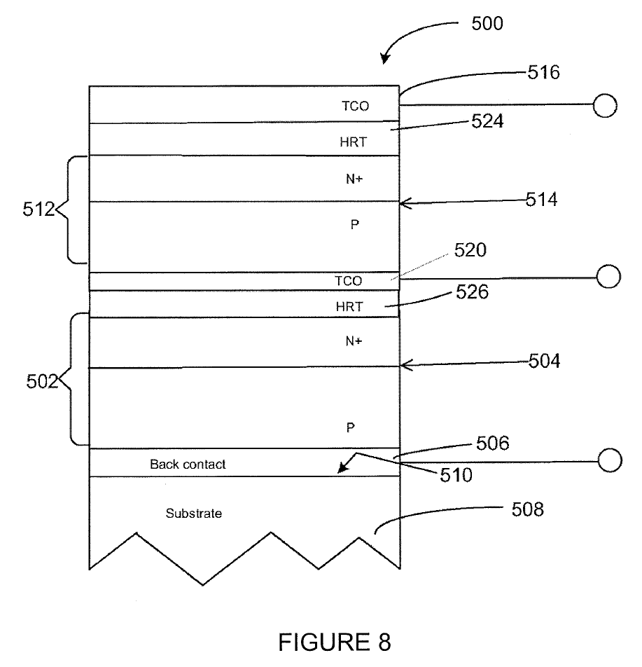

FIG. 8 is a simplified diagram illustrating a photovoltaic cell structure 500 for manufacturing a multi junction solar module according to another alternative embodiment of the present invention. Photovoltaic cell structure 500 is configured to have two junctions and three electrode terminals. As shown, photovoltaic cell structure 500 includes a lower cell 502 which includes a first pn^{|} junction 504. The lower cell can have a same material composition as the lower cell as described above in connection with the photovoltaic cell structure in FIG. 4. The lower cell is in electrical contact with a first electrode structure 506 which overlies a surface region 510 of a substrate member 508 also as described above for FIG. 4.

Photovoltaic cell structure 500 includes an upper cell 512 which includes a second pn⁻ junction 514. The upper cell can have a same material composition as the upper cell as described above in connection with the photovoltaic cell structure in FIG. 4. A second electrode structure 516 overlies and in electrical contact with the upper cell.

In a specific embodiment, a third conductor structure 520 is provided between the upper cell and the lower cell as shown in FIG. 8. The third conductor structure connects the upper cell and the lower cell in series in a specific embodiment. In a specific embodiment, the third conductor structure is characterized by a resistivity less than about 10 Ohm-cm. The third electrode structure can be made of a suitable material or a combination of materials. The third electrode structure is preferably made from a transparent conductive electrode or materials. Examples of the transparent conductive material can include indium tin oxide (ITO), aluminum doped zinc oxide, fluorine doped tin oxide and others. In an alternative embodiment, the third electrode structure may be made from a metal material. The metal material can include gold, silver, nickel, platinum, aluminum, tungsten, molybdenum, a combination of these, or an alloy, among others. In a specific embodiment, the metal material may be deposited using techniques such as sputtering, electroplating, electrochemical deposition and others. Yet alternatively, the third electrode structure may be made of a carbon based material such as carbon or graphite. In certain embodiments, the third electrode structure may be made of a conductive polymer material, depending on the application. Of course there can be other variations, modifications, and alternatives.

In certain embodiments, the photovoltaic cell structure 500 can include an optional first buffer layer 524 disposed between the second conductor structure and the upper cell as shown in FIG. 8. Photovoltaic cell structure 500 can also include an optional second buffer layer 526 provided between the third electrode structure and the lower cell. These buffer layers prevent diffusion of, for example, electrode materials into the respective photovoltaic cells in subsequent high temperature processing steps. In a specific embodiment, the buffer layers are characterized by a resistivity greater than about 10 kOhm-cm and can be provided using a suitable metal oxide. Of course there can be other variations, modifications, and alternatives.

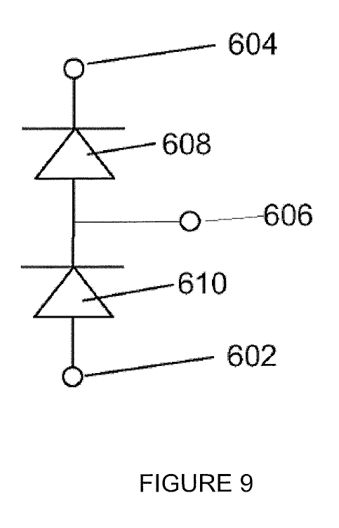

FIG. 9 is a simplified circuit representation 600 of the photovoltaic cell structure in FIG. 8. As shown in FIG. 9, the photovoltaic cell structure has 3 terminals 602, 604, and 606 provided by the first electrode structure, the second electrode structure, and the third electrode structure. The photo voltaic cell has two photodiodes 608 and 610 as provided by the upper cell and the lower cell. Of course one skilled in the art would recognize other variations, modifications, and alternatives.

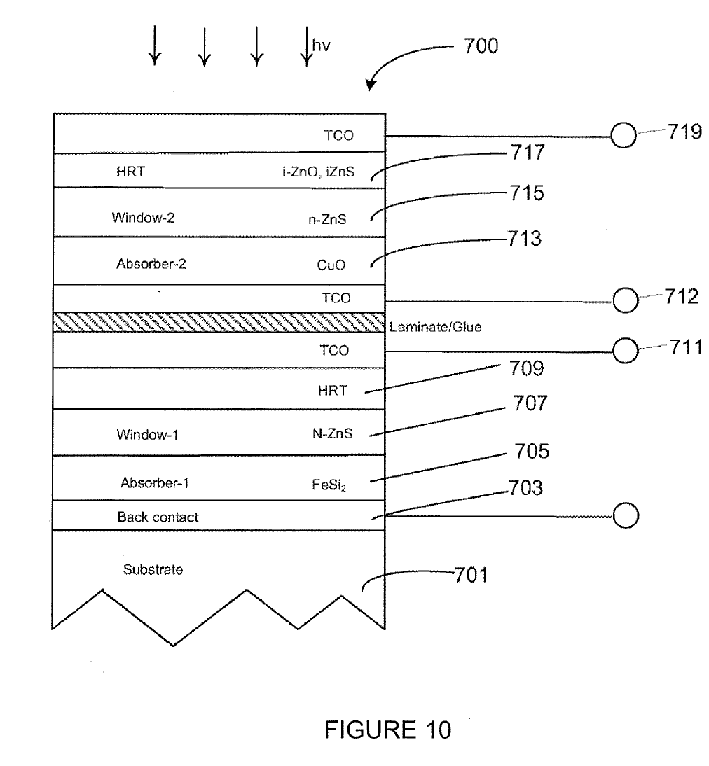

FIG. 10 is a simplified cross-sectional view of an example of a hetero junction cell 700 according to an embodiment of the present invention. As shown, the cell has a substrate 701 including a surface region. In a specific embodiment, the substrate can be a glass material, although other materials can be used. In a specific embodiment, the cell has a first conductor layer 703, which is a back contact, overlying the surface region. As an example, the back contact is a metal material. To define the lower cell structure, a first P type absorber comprising an iron disilicide material 705 is included. Further details of forming iron disilicide material have been described in U.S. patent applications Ser. No. 12/209,801 filed Sep. 12, 2008, which claims priority to U.S. Provisional Application No. 60/976,239, filed Sep. 28, 2007 and Ser. No. 12/210,173 filed Sep. 12, 2008, which claims priority to U.S. Provisional Application No. 60/976,317, filed Sep. 28, 2007, and hereby incorporated by reference for all purposes. In a specific embodiment, a first N⁺ type window layer is included. In a specific embodiment, the first N⁺ type window layer is provided by a N—ZnS material. In a specific embodiment, a high resistance transparent layer 709 overlies the first N⁺ type window layer. As an example, the high resistance layer can be intrinsic ZnS, intrinsic ZnO or other suitable materials.

Overlying the lower cell is a transparent conductive oxide 711, which can be ZnO (doped with aluminum), SnO₃ (doped with fluorine), or other suitable materials. Disposed between the lower and upper cells is a lamination layer and can be a glue layer, which is optically transparent. The lamination layer may be provided using an Ethylene vinyl acetate (EVA) material or a Polyvinyl butyral (PVB) material in a specific embodiment. To form an upper cell structure, a third transparent conductive oxide 712 is provided according to a specific embodiment. A second P type absorber layer 713 comprising a copper oxide material or other suitable material is formed overlying transparent conductive oxide 712. A second N⁺ type window layer 715 comprising an n-ZnS material is overlying the second P type absorber layer. In a specific embodiment, a second high resistance transparent layer 717 is overlying the second N⁺ type window layer. As an example, the second high resistance transparent layer 717 can be intrinsic ZnS, intrinsic ZnO, or other suitable materials. A transparent conductive oxide 719 is formed overlying high resistance transparent layer 717 according to a specific embodiment. Of course, depending upon the embodiment, the materials and/layers specified can be applied to other cell configurations such as three electrode, two electrode, and others.

Although the above has been illustrated according to specific embodiments, there can be other modifications, alternatives, and variations. For example, embodiments according to the present invention have been described using a two cell configuration. It is understood that the present invention can be extended to include N cells (N≧2). It is understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A multi junction photovoltaic cell device comprising:
a lower cell comprising:
a lower glass substrate material;
a lower electrode layer made of a reflective material overlying the glass material;
a lower absorber layer overlying the lower electrode layer, the absorber layer made of a semiconductor material having a band gap energy in a range of 0.7 to 1 eV;
a lower window layer overlying the lower absorber layer;
a lower transparent conductive oxide layer overlying the lower window layer;
an upper cell operably coupled to the lower cell, the upper cell comprising:
a p+ type transparent conductor layer overlying the lower transparent conductive oxide layer, the p+ type transparent conductor layer characterized by traversing electromagnetic radiation in at least a wavelength range from about 700 to about 630 nanometers and filtering electromagnetic radiation in a wavelength range from about 490 to about 450 nanometers;
an upper p type absorber layer overlying the p+ type transparent conductor layer, the p type conductor layer made of a semiconductor material having a band gap energy in a range of 1.6 to 1.9 eV;
an upper n type window layer overlying the upper p type absorber layer;
an upper transparent conductive oxide layer overlying the upper n type window layer;
an upper glass material overlying the upper transparent conductive oxide layer; and
four terminals including a first terminal coupled to the lower electrode layer through the lower glass substrate material, a second terminal coupled to the lower transparent conductive oxide layer, a third terminal coupled to the p+ type transparent conductor layer, and the fourth terminal coupled to the upper transparent conductive oxide layer through the upper glass material, wherein the second terminal is operably coupled to the third terminal via a glue layer.

2. The device of claim 1 wherein the lower absorber layer comprises semiconductor material selected from Cu₂SnS₃, FeS₂, or CuInSe₂, wherein the lower absorber layer has an optical absorption coefficient greater than about 10⁴ cm⁻¹ for electromagnetic radiation in a wavelength range of about 450 nm to about 700 nm.

3. The device of claim 1 wherein the glue layer comprises an EVA material.

4. The device of claim 1 wherein the glue layer comprises a PVB material.

5. The device of claim 1 wherein the lower electrode layer comprises material selected from aluminum, silver, gold, molybdenum, indium tin oxide (ITO), aluminum doped zinc oxide, or fluorine doped tin oxide and having a resistivity of less than about 10 Ohm-cm.

6. The device of claim 1 wherein the lower window layer comprises an n-type semiconductor material selected from cadmium sulfide or cadmium zinc sulfide and having a band gap energy greater than 2.5 eV.

7. The device of claim 1 wherein the lower transparent conductive oxide layer comprises a material selected from aluminum, silver, gold, molybdenum, indium tin oxide (ITO), aluminum doped zinc oxide, fluorine doped tin oxide, conductive polymer material, carbon and having a resistivity less than about 10 Ohm-cm.

8. The device of claim 1 wherein the p+ type transparent conductor layer comprises material selected from a zinc bearing species, a ZnTe species, and a material doped with at least one or more species selected from Cu, Cr, Mg, 0, Al, or N.

9. The device of claim 8 wherein the p+ type transparent conductor layer is characterized to selectively traverse electromagnetic radiation in at least a wavelength range from about 700 to about 630 nanometers and filter electromagnetic radiation in a wavelength range from about 490 to about 450 nanometers.

10. The device of claim 1 wherein the upper p type absorber layer comprises CuInS₂, Cu(In,Al)S₂, or Cu(In,Ga)S₂.

11. The device of claim 1 wherein the upper n type window layer comprises cadmium sulfide (CdS), zinc sulfide (ZnS), zinc selenium (ZnSe), zinc oxide (ZnO), or zinc magnesium oxide (ZnMgO) and is characterized by a band gap energy ranging from 2.5 eV to 5.0 eV.

12. The device of claim 1 wherein the upper transparent conductive oxide layer comprises In₂O₃:Sn (ITO), ZnO:Al (AZO), or SnO₂:F (TFO).

13. The device of claim 1 further comprising a buffer layer disposed between the upper transparent conductive oxide layer and the upper n-type window layer of the upper cell wherein the buffer layer is characterized by a resistivity greater than about 10 kOhm-cm.
